(19) United States
(12) Patent Application Publication
(10) Pub. No.: US 2010/0207112 A1
(43) Pub. Date: Aug. 19, 2010

(54) ORGANIC PHOTODETECTOR HAVING A REDUCED DARK CURRENT

(76) Inventors: Jens Fürst, Herzogenaurach (DE); Oliver Hayden, Herzogenaurach (DE); Günter Schmid, Hemhofen (DE)

Correspondence Address: King & Spalding LLP, 401 Congress Avenue, Suite 3200, Austin, TX, 78701, US

(21) Appl. No.: 12/680,586

(22) PCT Filed: Sep. 5, 2008
(86) PCT No.: PCT/EP08/61739

§ 371 Date: Mar. 29, 2010

(30) Foreign Application Priority Data
Sep. 28, 2007 (DE) 10 2007 046 444.6

(51) Int. Cl. H01L 51/44

(52) U.S. Cl. 257/40; 257/E51.012

(57) ABSTRACT

An organic photodetector has a reduced dark current by incorporating an electron blocking layer or barrier layer between the lower electrode and the organic photoactive layer. TA SAM layer is proposed as the material for the barrier layer.

### CROSS-REFERENCE TO RELATED APPLICATIONS

This application is a U.S. National Stage Application of International Application No. PCT/EP2008/061739 filed Sep. 5, 2008, which designates the United States of America, and claims priority to German Application No. 10 2007 046 444.6 filed Sep. 28, 2007, the contents of which are hereby incorporated by reference in their entirety.

### TECHNICAL FIELD

The invention relates to an organic photodetector having a reduced dark current by incorporating an electron blocking layer or barrier layer between the bottom electrode and the organic photoactive layer.

### BACKGROUND

Organic photodetectors based on organic semiconductor materials make it possible to produce pixelated flat panel detectors with high quantum efficiencies (50 to 85%) in the visible region of the spectrum. The thin organic layer systems used can be fabricated inexpensively using well-known processes such as spin coating, doctor blading or printing techniques, thus providing a price advantage particularly for larger area devices. Promising applications of such organic detector arrays are to be found e.g. in medical imaging as flat panel x-ray detectors, as here the light of a scintillator layer is typically detected on relatively large surface areas of at least a few centimeters.

The organic photodiodes consist e.g. of a vertical layer system: Au electrode/P3HT-PCBM blend/Ca—Ag electrode. Here the blend of the two components P3HT (absorber and hole transport component) and PCBM (electron acceptor and transport component) acts as a so-called bulk heterojunction, i.e. the separation of the charge carriers takes place at the interfaces of the two materials which are formed within the total layer volume.

A disadvantage of such detector arrays with large-area, unpatterned organic semiconductor layers is that, particularly if polymer materials (such as P3HT-PCBM blend) are used, the dark current is much higher than e.g. in the case of inorganic flat panel detectors. For a bias voltage of −5V, dark currents of the organic photodiodes are typically in the range 10⁻² to 10⁻³ mA/cm², whereas typical currents for detectors based on amorphous silicon, on the other hand, are less than 10⁻⁵ mA/cm².

A low dark current is particularly important if, as in the case of x-ray detectors, for example, a high dynamic range must be covered, i.e. if also very low light intensities must be detected above the noise level. Although a dark current contribution can basically be subtracted from the signal, it always results in a noise contribution which limits the dynamic range for measurements using low x-ray doses. Until now, inorganic flat panel x-ray detectors based on amorphous silicon, which have a very low dark current of less than 10⁻⁵ mA/cm², have therefore been commercially used. Efficient prior art organic photodiodes are either single-layer systems with a bulk heterojunction blend between an anode (ITO, gold, palladium, platinum, silver, etc.) and a cathode (e.g. Ca, Ba, Mg, LIF, ITO, etc. with subsequent capping layer of Ag or Al), or two-layer systems in which an additional hole transporter layer or electron blocking layer (typically PEDOT:PSS; PANI:PSS or a polyfluorene derivative) is also applied between the blend and the anode. The hole transport layer or blocking layer is normally used as a “buffer” layer with electrical properties for preventing short circuits due to possible “spikes” in the bottom electrode. The electrical properties consist of an electron blocking function in the reverse direction and at the same time undiminished hole extraction by the bottom electrode.

Glass, a polymer foil, metal or similar can be used as a substrate. Finally, a passivation layer or encapsulation with a transparent foil or glass substrate is mainly also provided.

The organic materials are usually applied by spin coating or doctor blading. For producing multilayer systems using these methods, the problem arises that, when an organic layer is applied to an existing organic layer, the solvent of the material to be applied partially or totally dissolves the existing layer, resulting in intermixing of the materials. To date, no polymer-based photodetector systems with sufficiently low dark current levels are known in the literature.

Solutions for reducing the dark current in the reverse direction have already been proposed in DE 10 2005 037 421, DE 10 2006 046 210 and DE 10 2005 037 421. These are based on the approach of appropriately modifying the layer between anode and photoactive layer so that the charge carriers causing the dark current are blocked.

### SUMMARY

According to various embodiments, an organically based photodetector can be provided whose dark current is reduced.

According to an embodiment, an organic photodetector may comprise a top electrode and a bottom electrode with at least one photoactive layer provided therebetween, wherein an electron blocking layer comprising at least one self-assembled monolayer is disposed between the photoactive layer and the bottom electrode.

According to a further embodiment, the SAM may contain molecules having in each case a head group with pi-pi interaction, an anchor group and, therebetween, a molecule chain. According to a further embodiment, the SAM may contain molecules having in each case a head group without interaction, an anchor group and, therebetween, a molecule chain. According to a further embodiment, in the photodetector with reverse structure, the cathode may form the bottom electrode on which the at least one SAM is disposed.

According to a further embodiment, the photodetector may contain molecules whose anchor groups are selected from the following group of compounds:

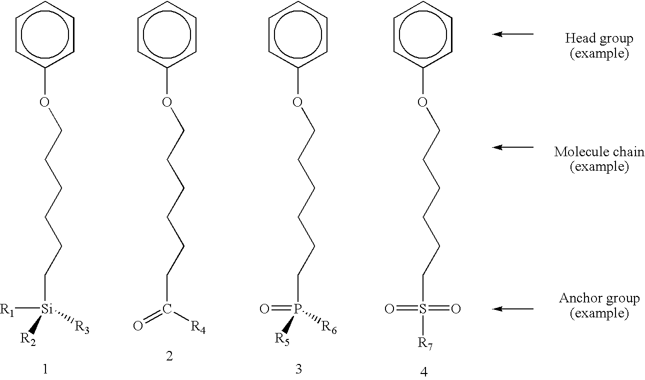

with the following residues: R₁, R₂, R₃=H, Cl, Br, I, OH, O-alkyl, where alkyl=methyl, ethyl, n-propyl, i-propyl, n-butyl, sec-butyl, tert-butyl, R₄=H, Cl, Br, I, OH, O—SiR₁R₂R₃; O-alkyl, where alkyl=methyl, ethyl, n-propyl, i-propyl, n-butyl, sec-butyl, tert-butyl, R₅, R₆=H, Cl, Br, I, OH, O-alkyl, where alkyl=methyl, ethyl, n-propyl, i-propyl, n-butyl, sec-butyl, tert-butyl, R₇=Cl, Br, I, OH; O-alkyl, where alkyl=methyl, ethyl, n-propyl, i-propyl, n-butyl, sec-butyl, tert-butyl and their branched and/or unbranched higher homologs. According to a further embodiment, the SAM may contain molecules whose molecule chain is selected from the following group of molecule chains:—alkyl chain with 2-20 carbon atoms in the chain;—fluorinated alkyl chain with 2-20 carbon atoms in the chain; alkyl chain with 2-20 carbon compounds and/or aryl groups as head groups and/or polyethylene glycol or a polyethylene diamine chain or any mixture of these molecule chains. According to a further embodiment, the SAM may contain molecules whose head group is selected from the group of following groups: methyl, fluorinated alkyl chain; phenoxy group and/or

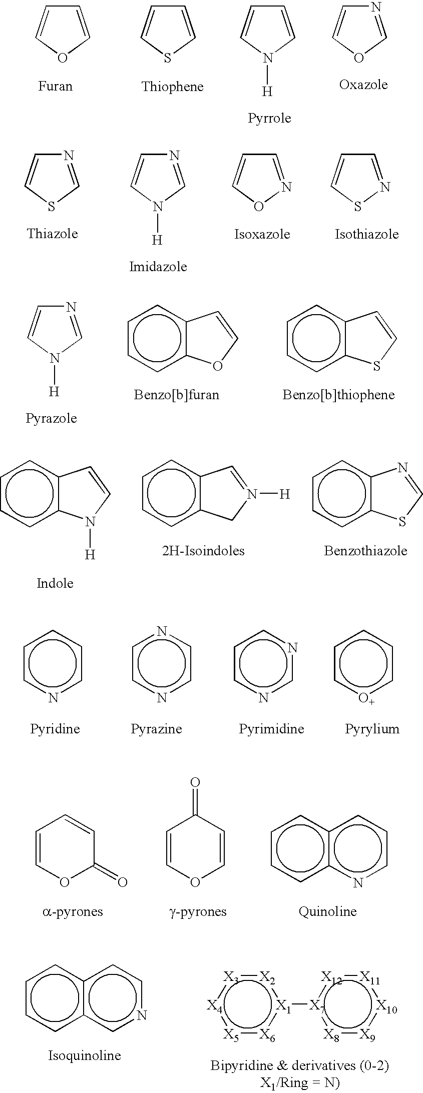

wherein the aromatics are bonded to the molecule chain either directly or via O, S, N, P, C═C, C═C and can carry any substituents. According to a further embodiment, the SAM can be obtained by deposition from the gas phase or by application from solution.

According to another embodiment, a SAM layer can be used between anode and photoactive layer of an organic photodetector, containing at least one monolayer of at least one self-assembled molecule type, wherein the molecules each contain at least one head group and one anchor group and a skeleton disposed therebetween.

According to yet another embodiment, a SAM layer can be used between anode and photoactive layer of an organic photodetector, wherein the SAM is selected from the SAMs as described above.

According to a further embodiment of the use, the SAM may contain a mixture of molecules so that it is matched in its barrier effect to the dark current and, by the position of its HOMO-LUMO levels, to the potential level of its surrounding layers.

### BRIEF DESCRIPTION OF THE DRAWINGS

FIG. 1 shows a standard layer system of an organic photodetector.

FIG. 2 shows the associated potential level diagram according to the prior art for the structure of FIG. 1.

FIG. 3 shows a potential level diagram for the device structure according to various embodiments with an additional electron blocking layer.

### DETAILED DESCRIPTION

According to various embodiments, an organic photodetector, may comprise a top and a bottom electrode with at least one photoactive layer therebetween, wherein there is disposed between the photoactive layer and the anode an electron blocking layer comprising at least one self-assembled monolayer (SAM). According to various embodiments, the use of a SAM layer between anode and photoactive layer of an organic photodetector, containing at least one monolayer of at least one self-assembled molecule type, the molecules each containing one head group and one anchor group as well as a skeleton disposed therebetween.

Self-assembled monolayers, hereinafter also referred to as SAMs, of the type that can be used according to various embodiments, are already known from documents DE 10328 811 A1, DE 10328810 A1, DE 10 2004 025 423 A1, DE 10 2004 022 603 A1, US 02005 01 89536 A1.

The suitability of the SAMs as an electron blocking layer in photodetectors is surprising in that, although the self-assembled layers described there were used as dielectrics, they were known as very thick layers due to their specific two-dimensional arrangement, so that it was hitherto not suspected that the SAMs would be usable as hole conducting and, because of their small thickness, completely transparent layers of the type required between bottom electrode and photoactive layer in the photodetector.

According to various embodiments, the problem of high dark currents can be avoided by inserting an additional electron blocking layer or barrier layer which efficiently reduces the dark current caused by negative charge carriers. Said layer is implemented by SAMs. The monolayers are covalently bonded on the electrode surface from the gas or liquid phase. In the case of thiol monolayers, barrier heights of 4-5 eV are achieved thereby (Ackermann et al, PNAS, 104, 11161 (2007)). In addition, it has been shown, taking alkyl-substituted oligothiophenes as an example, how the injection properties in an organic semiconductor depend on the length of the alkyl chain (M. Halik et. al. Adv. Mater. 15, 917 (2003)). The compounds discussed here are “adhered” to the substrate by a covalent bond, and as a result possess much higher bonding energies than the thiols.

This enables the barrier height of the junction to be influenced by varying the length of the alkyl chain in SAMs. The forward/reverse characteristics can be influenced via SAMs with conductive aromatic skeleton, depending on whether the aromatic function contains electron pulling or electron pushing substituents.

The deposition of a self-assembled monolayer on metals takes place, for example, via a chemical reaction resulting in the formation of a covalent bond between the anchor group of the SAM molecule and the metal layer. The adhesion of the SAM on the electrode surface is therefore excellent. The SAM molecules are linear molecules which are provided with a substrate-specific anchor group at one end. They form thin monomolecular films on surfaces. The film thickness is in the region of one molecule length and therefore between 0.5 and 5 nm. The SAMs form layers that are extremely chemically and thermally resistant, provided the anchor group and surface are optimally matched, q.v. also [1] Halik, M.; Klauk, H.; Zschieschang, U., Schmid, G.; Dehm, C., Schütz, M.; Maisch, S.; Effenberger, F.; Brunnbauer, M.; Stellacci, F.; “Low-voltage organic transistors with an amorphous molecular gate dielectric”, Nature 431 (2004) 963-966 and [2] Xia, Y.; Whitesides G. M.; “Softlithography”, Angew. Chem. 110 (1998) 568-594.

Examples of structures for SAM molecules are shown below. The head group can also be selected from the set of anchor groups.

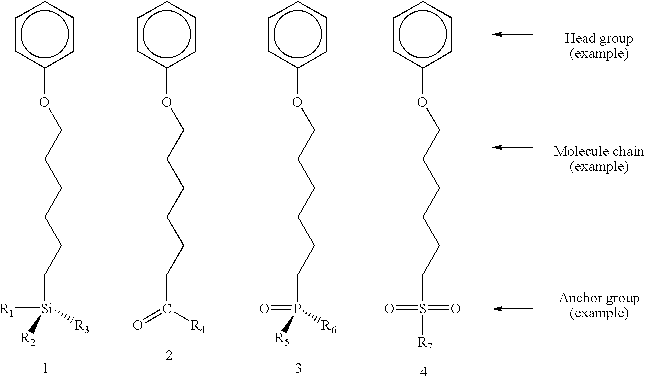

The following residues for the structures 1, 2, 3 and 4 shown may be mentioned by way of example and preference:

In 1, independently of one another, R₁, R₂, R₃=H, Cl, Br, I, OH, O-alkyl, where alkyl=methyl, ethyl, n-propyl, i-propyl, n-butyl, sec-butyl, tert-butyl, and can be their branched and/or unbranched higher homologs. The scope of the invention also includes groups such as benzyl, or unsaturated alkenyl groups. As a limiting factor, for example, at least one R₁, R₂ and R₃ is not H.

In 2, independently of one another, R₄=H, Cl, Br, I, OH, O—SiR₁R₂R₃; O-alkyl, where alkyl=methyl, ethyl, n-propyl, i-propyl, n-butyl, sec-butyl, tert-butyl, and can be their branched and/or unbranched higher homologs. The scope of the invention also includes groups such as benzyl, or unsaturated alkenyl groups. R₁, R₂, R₃ as in 1. For the case O—SiR₁R₂R₃, R₁, R₂, R₃ must be only alkyl or H

In 3, independently of one another, R₅, R₆=H, Cl, Br, I, OH, O-Alkyl, where alkyl=methyl, ethyl, n-propyl, i-propyl, n-butyl, sec-butyl, tert-butyl, and can be their branched and/or unbranched higher homologs. The scope of the invention also includes groups such as benzyl, or unsaturated alkenyl groups. The phosphonic acid anchor constitutes the particularly preferred variant.

In 4, independently of one another, R₇=Cl, —Br, I, OH; O-Alkyl, where alkyl=methyl, ethyl, n-propyl, i-propyl, n-butyl, sec-butyl, tert-butyl, and can be their branched and/or unbranched higher homologs. The scope of the invention also includes groups such as benzyl, or unsaturated alkenyl groups.

However, the scope of the invention also includes more complex anchor system such as, for example, hydroxamic acid-[2, 3], oxime-[2], isonitrile- and phosphine-based [2] anchor groups (see Folkers J. P; Gorman C. B.; Laibinis, P. E.; Buchholz, S; Whitesides G. M.; Nuzzo R. G.; “Self-Assembled Monolayers of Long-Chain Hydroxamic Acids on the Native Oxide of Metals”; Langmuir 11 (1995) 813-824).

The molecule chain determines the electrical properties of the self-assembled monolayer. In particular, its use as a dielectric has been extensively examined in DE 10328 811 A1, DE 10328810 A1, DE 10 2004 025 423 A1, DE 10 2004 022 603 A1, US 02005 01 89536 A1.

The publications cited above disclose the SAM layers which are preferably used according to various embodiments.

### Examples of Molecule Chains

a. Alkyl chains with 2-20 carbon atoms in the chain, with particular preference 10-18.

b. Fluorinated alkyl chains with 2-20 carbon atoms in the chain, with particular preference 10-18.

c. Alkyl chains with 2-20 carbon compounds and aryl groups as head groups analogously (DE 103 28 811 A1, and DE 103 28 810 A1). With particular preference 10-18. The aryl groups have a particularly advantageous effect on the stability of the SAM on the metal surface due to the formation of π-π interactions. The aryl groups can be substituted or unsubstituted. Substituents are again alkyl groups. (fluorinated, unsaturated, halogenes, containing S, N, P).

d. Instead of an alkyl chain, a polyethylene glycol or polyethylene diamine chain can be used.

e. Mixed variants from a-e.

By the mixing of different molecules in the SAM, the physical properties of the SAM such as conductivity, barrier effect, position of the HOMO/LUMO levels, transparency, etc. can be selectively adjusted.

The variants of the alkyl chains and the fluorinated alkyl chains carry as a head group a methyl, or fluorinated alkyl chain. The following aromatic SAM-stabilizing head groups are exemplary embodiments. Particularly preferred is the phenoxy group. The aromatics can be bonded to the molecule chain either directly or via 0, S, N, P, C═C, C═C. It is particularly advantageous if the head groups additionally carry anchor-group-containing substituents which again covalently bond the subsequent metal layer into the stack.

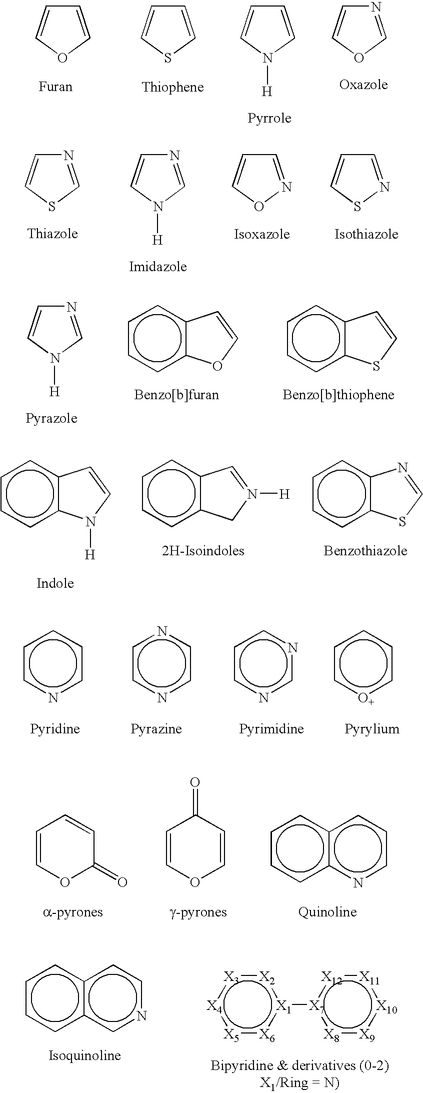

The possibility of deposition from the gas phase is particularly advantageous for constructing the multilayer system. For deposition from the gas phase, the substrate is exposed to the diluted or undiluted vapors of the corresponding compound for 0.1-10 min in a vacuum chamber. The preferred pressure is between 10⁻⁸ and 1000 mbar. Noble gases such as He, Ne, Ar, Kr or Xe or inert gases such as N₂ are used for the dilution. The preferred temperature is below 200° C. The silanes can generally be vaporized directly. In the case of the phosphonic acid, carboxylic acid and sulfonic acid anchors, their esters or reactive derivatives are particularly preferred, as they can be vaporized more easily. Following deposition, excess material is removed by pumping-out or heating of the substrate and if necessary by subsequent rinsing. The deposition of the next metal layer can then take place in the same vacuum chamber.

Alternatively, the SAM compound can also be applied from solution. Following deposition, a temperature step and/or light-exposure step is optionally inserted in order to complete the chemical reaction. The coated substrate is then rinsed with solvent to remove any excess SAM materials that are not bonded to the surface.

For deposition from solution, the SAM compound is dissolved in a concentration of 0.01-1000 mMol in a solvent or mixtures of the following:

a. Hydrocarbons, such as pentane, hexane, heptane, octane, etc., benzene, toluene, xylene, cresol, tetralin, decalin, etc.
b. Chlorinated hydrocarbons, such as dichloromethane, chloroform, carbon tetrachloride, trichloroethylene, chlorobenzene, dichlorobenzene, etc.
c. Alcohols such as methanol, n-propanol, i-propanol, butanol, etc.
d. Ethers and cyclic ethers such as diethyl ether, diphenyl ether, tetrahydrofuran, dioxane
e. Esters such as ethyl acetate
f. Dimethylformamide, dimethyl sulfoxide, N-methylpyrrolidinone, γ-butyrolactone, cyclohexanone, etc.

The deposition of the SAM on the surface takes place virtually spontaneously.

Reducing the dark current of organic photodetectors, especially in the case of reverse polarity, is an important necessity for making organic photodetectors suitable for industrial applications, self-assembled monolayers (SAMs) appearing to be a very good possibility for achieving this.

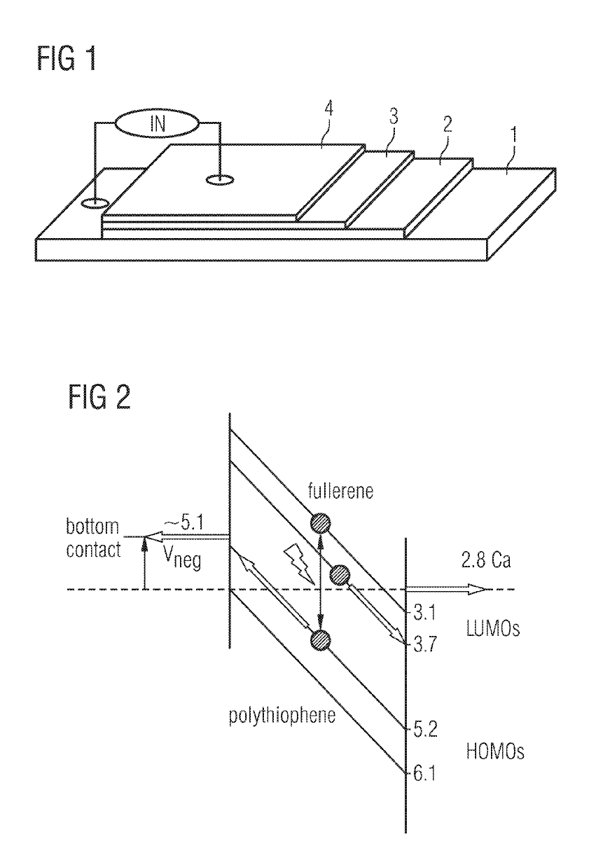

FIG. 1 shows a standard layer system of an organic photodetector. Disposed on a substrate 1 is the bottom electrode 2 which e.g. forms the anode and is made of gold. Disposed thereon in the case of the photodetector shown here as a single-layer system is the organic photoactive layer 3, e.g. consisting of a blend of two materials, polymers and fullerenes. The termination is formed by the top electrode 4, e.g. the calcium cathode with an aluminum capping layer.

FIG. 2 shows the associated potential level diagram according to the prior art for the structure of FIG. 1. This applies to the case of a negative bias voltage. As the active layer consists of a blend of two materials, the HOMO and LUMO levels of the two components are drawn parallel.

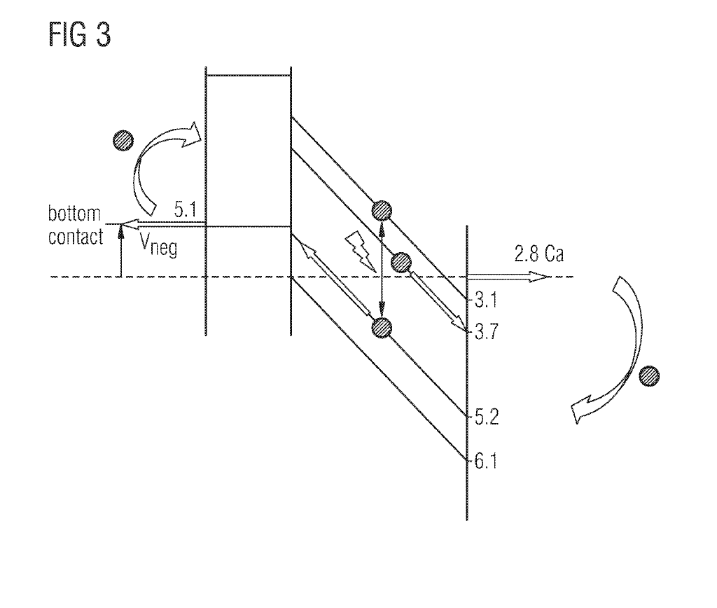

Lastly, FIG. 3 shows a potential level diagram for the device structure according to various embodiments with an additional electron blocking layer, e.g. between the bottom electrode and the hole transport layer or the organic photoactive layer. The HOMO level of the electron blocking layer is close to the HOMO level of the hole transport component and at the same time close to the energy level of the anode material, so that as far as possible no additional barrier to hole extraction is produced. The HOMO-LUMO energy gap is at the same time so high (>2.5 eV) that the LUMO level represents a barrier for the negative charge carriers. Indicated by arrows are the undesirable processes, electron injection at the anode and hole injection at the cathode, which can both contribute to the dark current, the first of which being considerably reduced by the additional electron blocking layer or barrier layer.

The organic photodetector can also be of reverse construction so that the SAM, if it is applied to the bottom electrode, connects to the cathode. A SAM can also, for example, be disposed between photoactive layer and top electrode.

The invention shows for the first time how SAM layers can be used in organic photodetectors.

What is claimed is:

1. An organic photodetector, comprising a top electrode and a bottom electrode with at least one photoactive layer provided therebetween, wherein an electron blocking layer comprising at least one self-assembled monolayer is disposed between the photoactive layer and the bottom electrode.

2. The photodetector according to claim 1, wherein the SAM contains molecules having in each case a head group with pi-pi interaction, an anchor group and, therebetween, a molecule chain.

3. The photodetector according to claim 1, wherein the SAM contains molecules having in each case a head group without interaction, an anchor group and, therebetween, a molecule chain.

4. The photodetector according to claim 1 with reverse structure, wherein the cathode forms the bottom electrode on which the at least one SAM is disposed.

5. The photodetector according to claim 1, wherein the photodetector contains molecules whose anchor groups are selected from the following group of compounds: 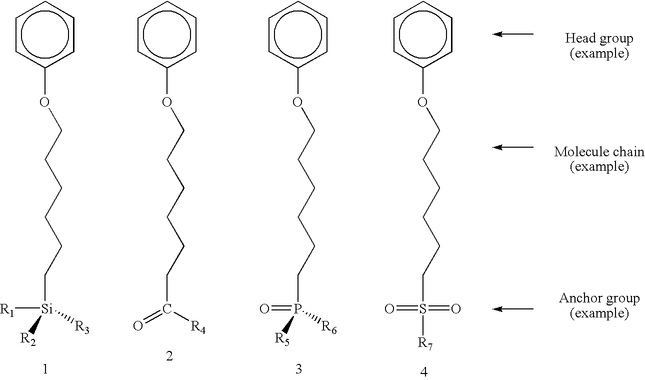
with the following residues: R₁, R₂, R₃=H, Cl, Br, I, OH, O-alkyl, where alkyl=methyl, ethyl, n-propyl, i-propyl, n-butyl, sec-butyl, tert-butyl, R₄=H, Cl, Br, I, OH, O—SiR₁R₂R₃; O-alkyl, where alkyl=methyl, ethyl, n-propyl, i-propyl, n-butyl, sec-butyl, tert-butyl, R₅, R₆=H, Cl, Br, I, OH, O-alkyl, where alkyl=methyl, ethyl, n-propyl, i-propyl, n-butyl, sec-butyl, tert-butyl, R₇=Cl, Br, I, OH; O-alkyl, where alkyl=methyl, ethyl, n-propyl, i-propyl, n-butyl, sec-butyl, tert-butyl and their branched and/or unbranched higher homologs.

6. The photodetector according to claim 1, wherein the SAM contains molecules whose molecule chain is selected from the following group of molecule chains:—alkyl chain with 2-20 carbon atoms in the chain;
fluorinated alkyl chain with 2-20 carbon atoms in the chain;
alkyl chain with 2-20 carbon compounds and/or aryl groups as head groups and/or
polyethylene glycol or a polyethylene diamine chain or any mixture of these molecule chains.

7. The photodetector according to claim 1, wherein the SAM contains molecules whose head group is selected from the group of following groups:
methyl, fluorinated alkyl chain; phenoxy group and/or 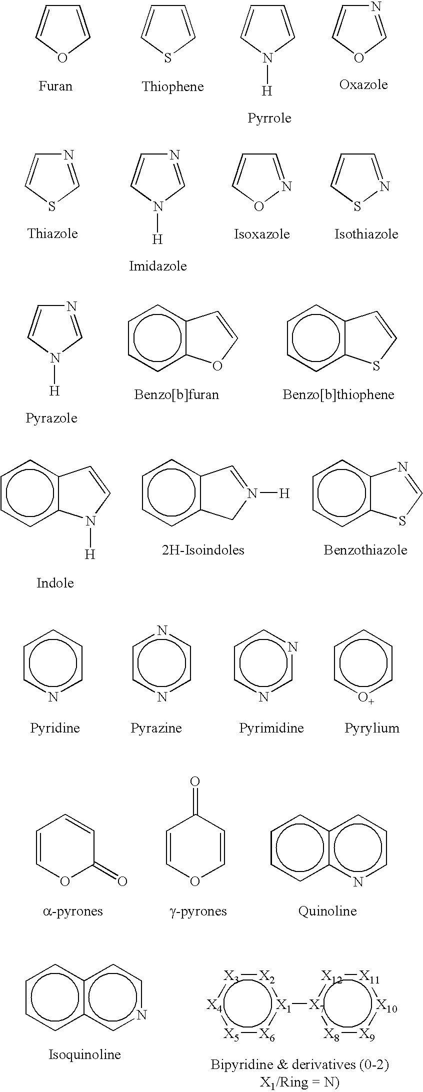
wherein the aromatics are bonded to the molecule chain either directly or via 0, S, N, P, C═C, C═C and can carry any substituents.

8. The photodetector according to claim 1, wherein the SAM can be obtained by deposition from the gas phase or by application from solution.

9. A method comprising the step of using SAM layer between anode and photoactive layer of an organic photodetector, containing at least one monolayer of at least one self-assembled molecule type, wherein the molecules each contain at least one head group and one anchor group and a skeleton disposed therebetween.

10. A method comprising the step of using a SAM layer selected from the group of SAMs as claimed in claim 3, wherein the SAM layer is used between anode and photoactive layer of an organic photodetector.

11. The method according to claim 9, wherein the SAM contains a mixture of molecules so that it is matched in its barrier effect to the dark current and, by the position of its HOMO-LUMO levels, to the potential level of its surrounding layers.

12. The method according to claim 10, wherein the SAM contains a mixture of molecules so that it is matched in its barrier effect to the dark current and, by the position of its HOMO-LUMO levels, to the potential level of its surrounding layers.

13. A method comprising the step of using a SAM layer selected from the group of SAMs as claimed in claim 4, wherein the SAM layer is used between anode and photoactive layer of an organic photodetector.

14. A method comprising the step of using a SAM layer selected from the group of SAMs as claimed in claim 5, wherein the SAM layer is used between anode and photoactive layer of an organic photodetector.

15. A method comprising the step of using a SAM layer selected from the group of SAMs as claimed in claim 6, wherein the SAM layer is used between anode and photoactive layer of an organic photodetector.
